(19) United States
(12) Patent Application Publication
(10) Pub. No.: US 2007/0045630 A1
(43) Pub. Date: Mar. 1, 2007

(54) Electroluminescence apparatus and manufacturing method of the same

(76) Inventor: Naoyuki Toyoda, Suwa-shi (JP)

Correspondence Address: HARNESS, DICKEY & PIERCE, P.L.C., P.O. BOX 828, BLOOMFIELD HILLS, MI, 48303, US

(21) Appl. No.: 11/507,371

(22) Filed: Aug. 21, 2006

(30) Foreign Application Priority Data
Aug. 22, 2005 (JP) 2005-240419
Aug. 22, 2005 (JP) 2005-240420
Aug. 22, 2005 (JP) 2005-240421
Aug. 3, 2006 (JP) 2006-212324

(51) Int. Cl. H01L 29/04

(52) U.S. Cl. 257/72

(57) ABSTRACT

Quadrangular prism-like EL bars are each formed by depositing a light emitting layer and a positive hole transport layer on an outer surface of a data line. The EL bars are arranged in such a manner that each of the EL bars crosses a plurality of scanning lines formed on a transparent substrate. A sealing substrate presses the EL bars against the scanning lines. A sealing layer is formed along the outer circumference of the sealing substrate and the outer circumference of the transparent substrate. The sealing layer seals the space between the sealing substrate and the transparent substrate (that accommodates the data lines, the light emitting layers, the positive hole transport layers, and the scanning lines). This configuration facilitates design changing of an electroluminescence apparatus including modification of the size of the apparatus, the pixel size, and the type of the functional layers, thus improving productivity.

### CROSS-REFERENCE TO RELATED APPLICATIONS

This application is based upon and claims the benefit of priority from prior Japanese Patent Application Nos. 2005-240419, 2005-240420, and 2005-240421, each filed on Aug. 22, 2005, and Japanese Patent Application No. 2006-212324, filed on Aug. 3, 2006, the entire contents of which are incorporated herein by reference.

### BACKGROUND OF THE INVENTION

The present invention relates to an electroluminescence apparatus and a method for manufacturing the electroluminescence apparatus.

An electroluminescence apparatus (hereinafter, referred to as an “EL apparatus” when necessary) is generally known as a display. The EL apparatus displays an image in correspondence with display data. The EL apparatus has a cathode and an anode in each of the pixels. A functional layer including a light emitting layer, a positive hole transport layer, and an electron transport layer is provided between the cathode and anode. The EL apparatus displays an image corresponding to the display data by controlling the drive current supplied to the functional layer and the drive time of the functional layer.

To enhance brightness of the image and save power consumption, an organic EL apparatus that has a functional layer formed of organic material is known as an EL apparatus. The organic material used in the organic EL apparatus exhibits low tolerance to photolithography. Thus, in the manufacture of the organic EL apparatus, the functional layer has been formed through patterning by vapor deposition using a mask. However, since traveling of particles (organic low molecules) to be deposited is difficult to control, machining accuracy of the functional layer cannot be improved by the vapor deposition. This significantly decreases productivity for manufacturing the organic EL apparatus.

To facilitate patterning of a functional layer of an organic EL apparatus and improve productivity for manufacturing the EL apparatus, JP-A-2005-116313 has proposed formation of a liquid repellent barrier that encompasses an anode. A droplet of liquid containing light emitting material is ejected onto a zone encompassed by the barrier (on the anode). A functional layer with a predetermined thickness is thus provided in a self-aligning manner by drying the liquid droplet. In this manner, the patterning of the functional layer is facilitated and the productivity for manufacturing the EL apparatus is improved.

However, in the above-described process for manufacturing the organic EL apparatus, to ensure such improved productivity and stability of organic material, all of the pixels are formed by common formation steps (for example, a common liquid ejection step, a common drying step, and a common upper layer formation step).

Therefore, if a larger-sized EL apparatus is to be manufactured, the formation area of a functional layer formed by a single formation step is enlarged. Thus, when drying droplets, interaction among the droplets in the pixels occurs in a wider range, leading to, for example, increase of partial pressure of solvent. This varies the speed at which drying of the droplets happen. Also, if some of the pixels must be formed in altered sizes, droplets of pixels of the original size that have been already provided interact with the droplets of the pixels of the altered sizes. This decreases uniformity of the thickness of the functional layer. Further, if a portion of a functional layer must be formed of different material, droplets of pixels formed of the original material that have been already provided interact with the droplets of the pixels formed of the different material. The uniformity of thickness of the functional layer thus decreases.

Accordingly, in the above-described EL apparatus, all of the conditions for forming the functional layer must be reconsidered in accordance with any of the changes to the design of the EL apparatus. This significantly reduces the productivity for manufacturing the EL apparatus.

### SUMMARY

It is an objective of the present invention to provide an electroluminescence apparatus and a method for manufacturing the electroluminescence apparatus that improve productivity by facilitating changes to the design of the electroluminescence apparatus including modifications to the size of the electroluminescence apparatus, the sizes of the pixels, and the types of the functional layers.

An aspect of the present invention is an electroluminescence apparatus having a transparent substrate, a plurality of transparent electrodes aligned on a surface of the transparent substrate, and a plurality of light emitting bars. Each of the light emitting bars includes a bar-like opposing electrode and a functional layer. The functional layer includes a light emitting layer deposited on an outer surface of the opposing electrode. A holding portion holds the light emitting bars with respect to the surface of the transparent substrate in such a manner that the functional layers are each connected to the transparent electrodes.

Another aspect of the invention is a method for manufacturing an electroluminescence apparatus. The method includes aligning a plurality of transparent electrodes on a surface of a transparent substrate; forming a plurality of light emitting bars by providing a functional layer including a light emitting layer on an outer surface of each of bar-like opposing electrodes; and securing the light emitting bars to the surface of the transparent substrate in such a manner that the functional layers are each connected to the transparent electrodes.

Other aspects and advantages of the invention will become apparent from the following description, taken in conjunction with the accompanying drawings, illustrating by way of example the principles of the invention.

### BRIEF DESCRIPTION OF THE DRAWINGS

The features of the present invention that are believed to be novel are set forth with particularity in the appended claims. The invention, together with objects and advantages thereof, may best be understood by reference to the following description of the presently preferred embodiments together with the accompanying drawings in which:

FIG. 1 is a perspective view schematically showing an EL apparatus according to a first embodiment of the present invention;

FIG. 2 is an enlarged perspective view showing a main portion of the EL apparatus of FIG. 1;

FIG. 3 is a perspective view for explaining a method for forming a transparent electrode of FIG. 1;

FIG. 4 is a cross-sectional view for explaining a method for forming a light emitting layer of FIG. 2;

FIG. 5 is a cross-sectional view for explaining a method for forming a functional layer of FIG. 2;

FIG. 6 is a perspective view for explaining a method for manufacturing the EL apparatus of FIG. 1;

FIG. 7 is an enlarged perspective view showing a main portion of an EL apparatus according to a second embodiment of the present invention;

FIG. 8 is a plan view showing a portion of the EL apparatus of FIG. 7;

FIG. 9 is a cross-sectional view for explaining a method for manufacturing a light emitting layer of FIG. 7;

FIG. 10 is a cross-sectional view for explaining a method for forming a functional layer of FIG. 7; and

FIG. 11 is an enlarged perspective view showing a main portion of an EL apparatus according to a third embodiment of the present invention.

### DETAILED DESCRIPTION OF THE PREFERRED EMBODIMENTS

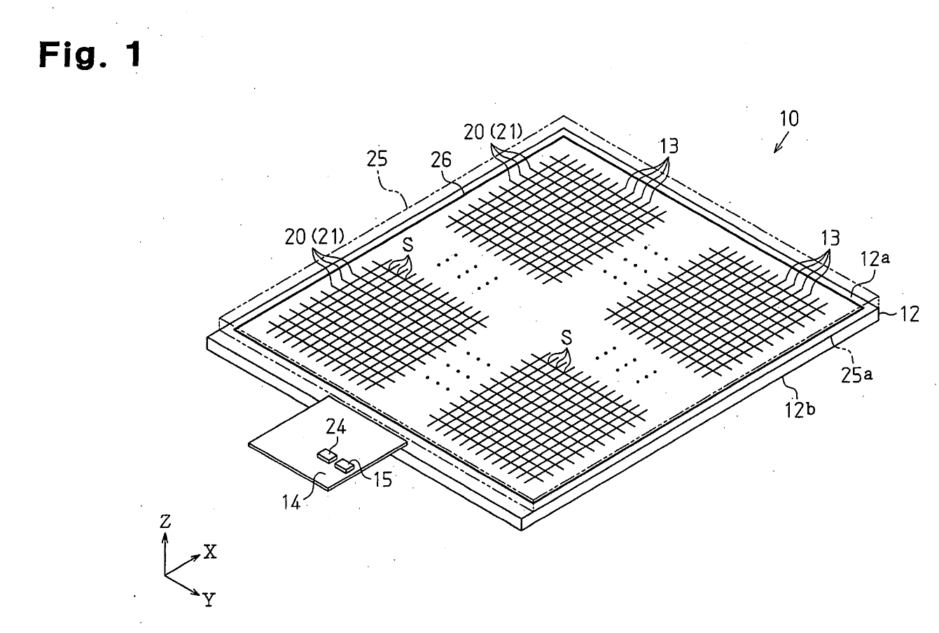

A first embodiment of the present invention will now be described with reference to FIGS. 1 to 6. As shown in FIG. 1, an EL apparatus 10 has a rectangular plate-like transparent substrate 12. The transparent substrate 12 is formed of transparent organic material such as non-alkaline glass or transparent resin material such as polyethylene terephthalate, polyethylene naphthalate, or polymethyl methacrylate. Although the size of the transparent substrate 12 is relatively large, or approximately 2400 mm×approximately 2200 mm (dimension in direction X×dimension in direction Y), the transparent substrate 12 is not restricted to this size.

A plurality of (m) scanning lines 13, which form transparent electrodes, are arranged on a surface of the transparent substrate 12, or a scanning line forming surface 12a. Each of the scanning lines 13 is formed in an elongated shape extending in direction X. The scanning lines 13 are spaced at equal intervals in direction Y. Each scanning line 13 is an anode formed of light transmissible conductive material with a great work function (for example, ITO (Indium-Tin-Oxide)). The scanning lines 13 are each electrically connected to a scanning line driver circuit 15 through an FPC (a flexible substrate) 14, which is connected to an end of the transparent substrate 12. The scanning line driver circuit 15 generates scanning signals in correspondence with different control signals and clock signals sent from a non-illustrated control circuit. The scanning line driver circuit 15 sequentially selects certain one of the scanning lines 13 at predetermined points of time. The scanning signals are sent to the selected ones of the scanning lines 13.

A plurality of (n) electroluminescence bars (hereinafter, referred to simply as “EL bars”) 20, or light emitting bars, are provided on the scanning lines 13. Each of the EL bars 20 is formed in a quadrangular prism-like shape extending in direction Y. In other words, each EL bar 20 has a rectangular cross-sectional shape as viewed in the axial direction of the EL bar 20. The EL bars 20, which have elongated shapes, are spaced at equal intervals in direction X in such a manner as to cross the scanning lines 13.

In the first embodiment, the n EL bars 20 and the m scanning lines 13 mutually intersect to form “pixel areas S”, the number of which is represented by m×n. Each of the pixel areas S is formed by a crossing portion between each one of the EL bars 20 and the crossing one of the scanning lines 13.

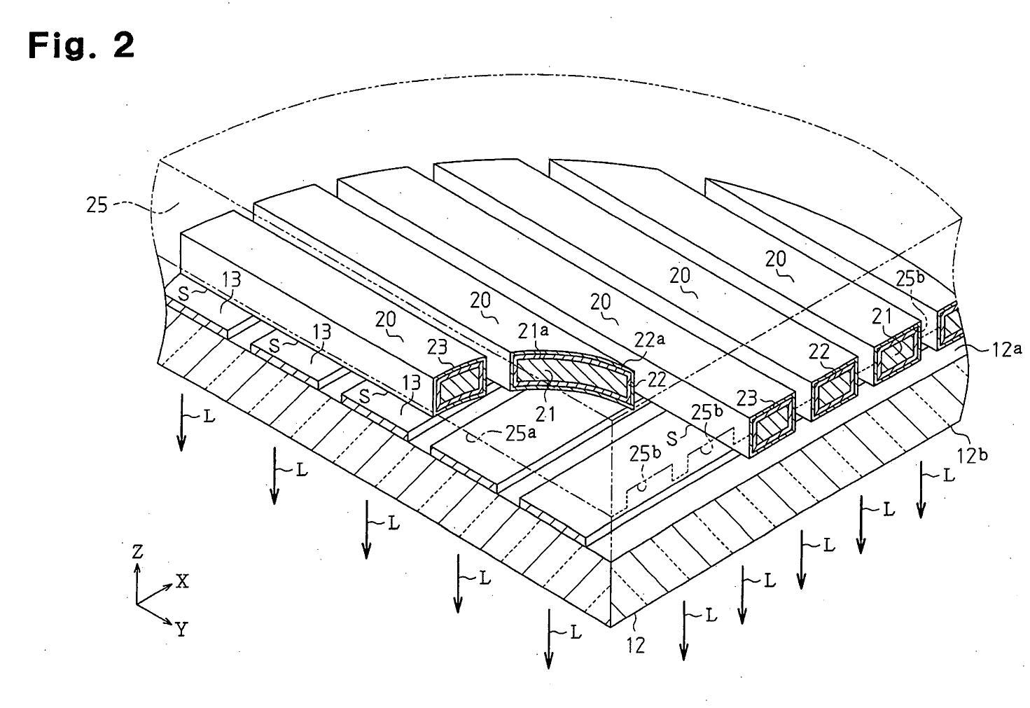

As shown in FIG. 2, a data line 21 is provided in each EL bar 20 as an opposing electrode. A light emitting layer 22 and a positive hole transport layer 23 are formed on an outer surface 21a of each of the data lines 21 in this order from the side corresponding to the data line 21 toward the side corresponding to the exterior.

Each of the data lines 21 is a cathode having a quadrangular prism-like shape extending in direction Y. The data lines 21 are formed of conductive material with a small work function (for example, metal elemental substances such as Li, Mg, Ca, Sr, La, Ce, Er, Eu, Sc, Y, Yb, Ag, Cu, Al, Cs, Rb). Each data line 21 is sized by 1 mm×2000 mm×0.5 mm, dimension in direction X×dimension in direction Y×dimension in direction Z. However, the size of each data line 21 is not restricted to this.

Referring to FIG. 1, the data lines 21 are each electrically connected to a data line driver circuit 24 through the FPC 14. The data line driver circuit 24 generates data signals in correspondence with different control signals and display data provided by a non-illustrated control circuit. The data line driver circuit 24 outputs data signals to corresponding ones of the data lines 21 at predetermined points of time.

As illustrated in FIG. 2, each of the light emitting layers 22 is an organic layer formed with uniform thickness on the entire outer surface 21a of the corresponding one of the data lines 21. In other words, each light emitting layer 22 covers all of the four side surfaces of the data line 21, which has the quadrangular prism-like shape. The light emitting layers 22 are formed of fluorene-dithiophene copolymer (hereinafter, referred to simply as “F8T2”), which is light emitting layer material. Electrons provided in correspondence with the data signal input to each data line 21 are injected into the corresponding light emitting layer 22.

The light emitting layer material is not restricted to “F8T2” but may be any one of the following publicly known low molecular or high molecular light emitting layer materials.

The low molecular light emitting layer materials include, for example, cyclopentadiene derivatives, tetraphenylbutadiene derivatives, triphenylamine derivatives, oxadiazole derivatives, distyrylbenzene derivatives, thiophene cyclic compounds, pyridine cyclic compounds, perinone derivatives, perylene derivatives, coumarin derivatives, and metal complexes such as aluminum quinolinol complexes, benzoquinolinol beryllium complexes, benzoxazole zinc complexes, benzothiazole zinc complexes, azomethyl zinc complexes, porphyrin zinc complexes, and europium complexes.

The high molecular light emitting layer materials include, for example, polyparaphenylene vinylene derivatives, polyparaphenylene derivatives, polysilane derivatives, polyacetylene derivatives, polythiophene derivatives, polyvinyl carbazol, polyfluorenone derivatives, polyquinoxaline derivatives, polyvinylene stylene derivatives, copolymers formed from these derivatives, and different types of dendrimers including triphenylamine or ethylenediamine as molecular nuclei.

Each of the positive hole transport layers 23 is formed with uniform thickness on the entire portion of an outer surface 22a of the corresponding one of the light emitting layers 22. Each positive hole transport layer 23 is formed of poly(3,4-ethylene dioxithyophene) (hereinafter, referred to simply as “PEDOT”), or positive hole transport layer material. Each of the positive hole transport layers 23 is electrically connected to the scanning lines 13, which are provided by the number m, through surface contact between the positive hole transport layer 23 and the scanning lines 13. The positive hole transport layer 23 transports positive holes that have been injected from the scanning lines 13 to a portion of the light emitting layer 22 corresponding to each of the associated pixel areas S.

The positive hole transport layer material is not restricted to “PEDOT” but may be any one of the following publicly known low-molecular or high-molecular light emitting layer materials.

The low molecular positive hole transport layer materials include, for example, benzidine derivatives, triphenylmethane derivatives, phenylenediamine derivatives, styrylamine derivatives, hydrazone derivatives, pyrazoline derivatives, carbazole derivatives, and porphyrin compounds.

The high molecular positive hole transport layer materials include high molecular compounds containing any of the above-listed low molecular structures (as a main chain or a side chain), polyaniline, polythiophenevinylene, polythiophene, α-naphthylphenyljiamine, mixtures of “PEDOT” and polystyrene sulfonate (Baytron P, trade mark of Bayer Corporation), and different types of dendrimers containing triphenylamine or ethylenediamine as molecular nuclei.

As indicated by the double-dotted chain lines of FIG. 2, a sealing substrate 25, or a holding substrate forming a holding portion, is provided over the EL bars 20. The sealing substrate 25 has a gas barrier property. A surface of the sealing substrate 25 opposed to the transparent substrate 12, or a holding surface 25a, has a plurality of guide grooves 25b extending in direction Y. The guide grooves 25b are spaced at equal intervals in direction X. The guide grooves 25b, each of which is a recessed groove, are arranged at positions corresponding to the EL bars 20. The lateral width of each guide groove 25b is substantially equal to the dimension (the lateral width) of each EL bar 20 in direction X. Each guide groove 25b guides the corresponding EL bar 20 in direction Y.

As illustrated in FIG. 1, a rectangular frame-like sealing layer 26 is formed between the sealing substrate 25 and the transparent substrate 12 and extends along the outer circumferences of the sealing substrate 25 and the transparent substrate 12. The sealing layer 26 is an organic or inorganic, light transmissible high-molecular film having a gas barrier property. The sealing substrate 25 is (the EL bars 20 are) held in tight contact with the transparent substrate 12 (the scanning lines 13) through the sealing layer 26. The sealing layer 26 seals the space between the sealing substrate 25 and the transparent substrate 12 (the space accommodating the data lines 21, the light emitting layers 22, the positive hole transport layers 23, and the scanning lines 13). In other words, the sealing layer 26 prevents moisture and oxygen from entering this space from the exterior.

In accordance with line progressive scan performed by the scanning line driver circuit 15, the scanning lines 13 are sequentially selected one by one. Data signals are sequentially sent from the data line driver circuit 24 to the corresponding ones of the data lines 21. As a result, in the pixel areas S associated with the selected ones of the scanning lines 13, positive holes and electrons provided in correspondence with the scanning signals and the data signals, respectively, are injected from the scanning lines 13 and the data lines 21, respectively, into the associated light emitting layers 22. The positive holes and the electrons then recombine together in each of the light emitting layers 22 associated with the pixel areas S, thus generating excitons (exciters). The excitons then restore the ground states and releases energy, which emits fluorescent or phosphorescent light L. The light L generated in each of the pixel areas S passes through the scanning line 13 opposed to the pixel area S and the transparent substrate 12 and exits the transparent substrate 12 through a display surface 12b. The display surface 12b opposes the scanning line forming surface 12a of the transparent substrate 12. In this manner, an image based on the display data is displayed on the display surface 12b of the transparent substrate 12.

Next, a method for manufacturing the EL apparatus 10 will be explained.

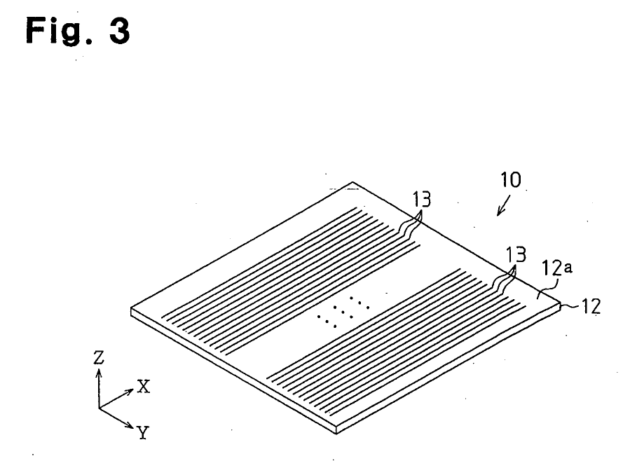

First, as shown in FIG. 3, the multiple scanning lines 13 are formed on the scanning line forming surface 12a of the transparent substrate 12 (a scanning line formation step as a transparent electrode formation step). That is, by a liquid phase process such as a screen printing method or an inkjet method using light transmissible conductive material or a gas phase process such as a vapor deposition method or a sputtering method, the scanning lines 13 are provided on the scanning line forming surface 12a of the transparent substrate 12, extending in direction X.

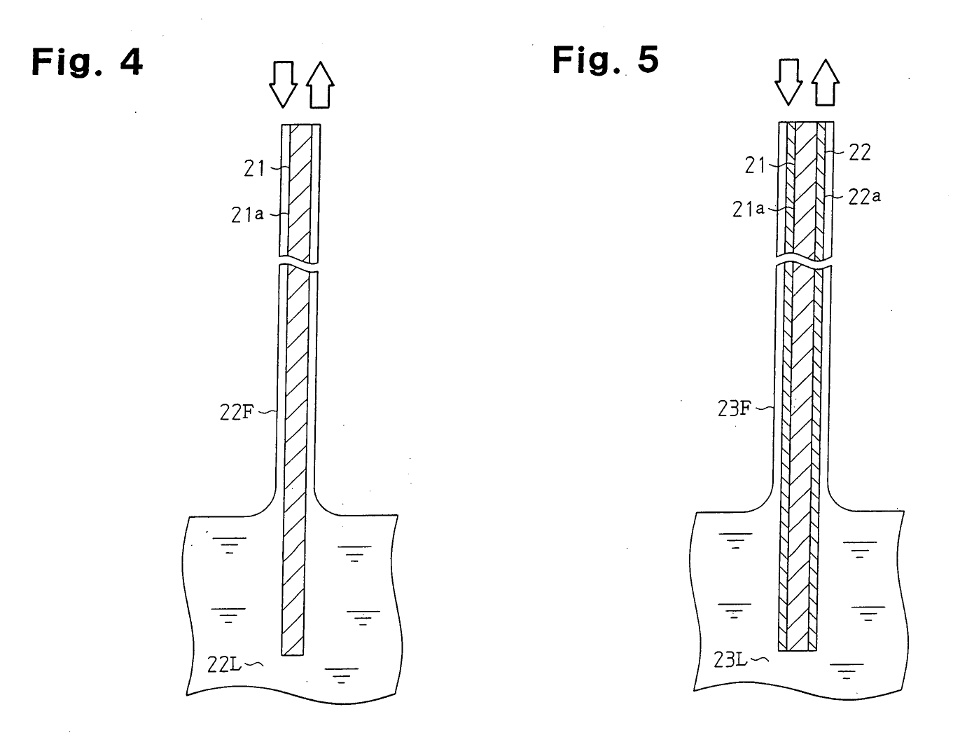

Formation of the scanning lines 13 is followed by a light emitting layer formation step, which is a first part of a light emitting bar formation step. Specifically, as illustrated in FIG. 4, each of the data lines 21 separate from the transparent substrate 12 is immersed in liquid (light emitting layer forming liquid 22L) containing the aforementioned “F8T2” and then removed from the liquid 22L. A liquid film 22F, which has deposited on the outer surface 21a of each of the data lines 21, is then dried to obtain the light emitting layer 22. In this manner, the light emitting layers 22 are each formed in a step that does not involve the transparent substrate 12.

Following formation of the light emitting layer 22, a positive hole transport layer formation step, a second part of the light emitting bar formation step, is executed. That is, referring to FIG. 5, each of the data lines 21 in which the light emitting layer 22 has been formed is immersed in liquid (positive hole transport layer forming liquid 23L) containing the “PEDOT” and removed from the liquid 23L. A liquid film 23F formed by the positive hole transport layer forming liquid 23L, which has deposited on the outer surface 22a of the light emitting layer 22, is then dried to form the positive hole transport layer 23. In this manner, like the light emitting layers 22, the positive hole transport layers 23 are each provided in a step that does not involve the transparent substrate 12. The light emitting layers 22 function with the EL bars 20 secured to the transparent substrate 12 (the scanning lines 13).

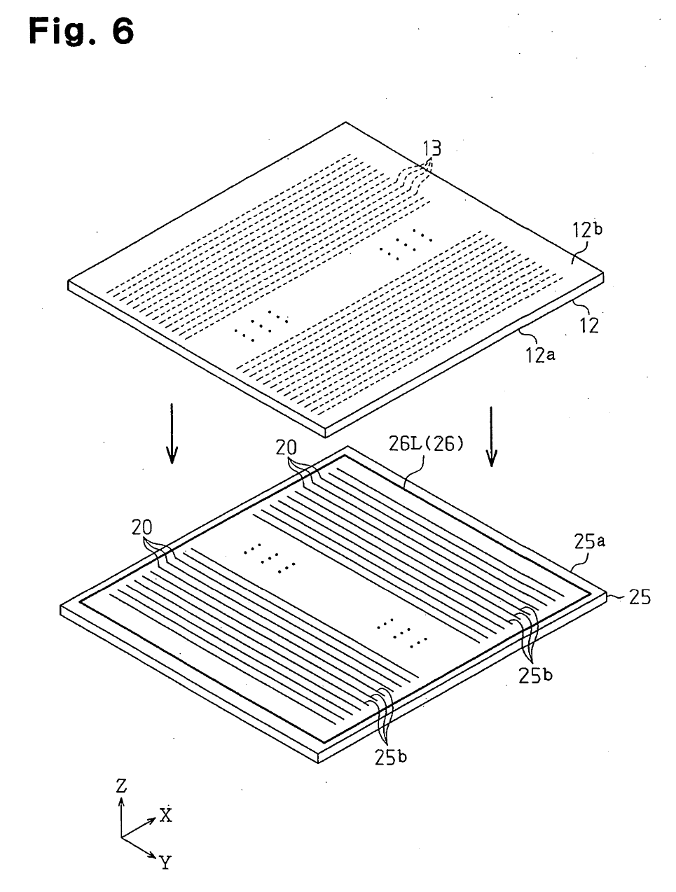

After providing the EL bars 20 by forming the light emitting layers 22 and the positive hole transport layers 23 as has been described, a light emitting bar securing step is performed for securing the EL bars 20 to the transparent substrate 12. Specifically, with reference to FIG. 6, the EL bars 20 are placed in the corresponding guide grooves 25b of the sealing substrate 25 with the holding surface 25a facing upward. After arranging the EL bars 20 on the sealing substrate 25, ultraviolet curing resin 26L is applied to the outer circumference of the sealing substrate 25. The sealing substrate 25 and the transparent substrate 12 are then transported to a depressurized atmosphere of inactive gas. The transparent substrate 12 is then mounted on and bonded with the sealing substrate 25 in such a manner that the EL bars 20 cross the scanning lines 13. The transparent substrate 12 and the sealing substrate 25 in the bonded state are then exposed to the atmospheric air. The ultraviolet curing resin 26L is thus irradiated with ultraviolet rays and cured.

In this manner, the scanning lines 13 and the EL bars 20 are clamped between the transparent substrate 12 and the sealing substrate 25. As a result, the transparent substrate 12 is held in tight contact with the sealing substrate 25. Further, since the scanning lines 13 are pressed against the EL bars 20 (the positive hole transport layers 23) by the atmospheric pressure, electric connection between the positive hole transport layers 23 and the scanning lines 13 is further reliably brought about. Also, the inactive gas sealed in the space between the transparent substrate 12 and the sealing substrate 25 ensures electric stability of each of the EL bars 20.

The first embodiment has the following advantages.

(1) In the first embodiment, the EL bars 20 having the quadrangular prism-like shapes are each formed by sequentially depositing the light emitting layer 22 and the positive hole transport layer 23 on the outer surface 21a of each data line 21. The EL bars 20 are aligned on the scanning lines 13 of the transparent substrate 12. The EL bars 20 are pressed against the scanning lines 13 by the sealing substrate 25. The sealing layer 26 is provided along the outer circumferences of the sealing substrate 25 and the transparent substrate 12 for sealing the space between the sealing substrate 25 and the transparent substrate 12 (the space accommodating the data lines 21, the light emitting layers 22, the positive hole transport layers 23, and the scanning lines 13).

Therefore, simply by increasing the number of the EL bars 20, the EL apparatus 10 is enlarged in size without degrading uniformity of the thickness of the light emitting layers 22 and that of the positive hole transport layers 23. Since such enlarging of the EL apparatus 10 is achieved by applying an existing manufacturing process, the EL apparatus 10 is enlarged easily. This improves productivity for manufacturing the EL apparatus 10.

(2) In the first embodiment, it is unnecessary to provide a larger apparatus or a larger auxiliary equipment for forming the light emitting layers 22 or the positive hole transport layers 23. This further facilitates upsizing of the EL apparatus 10.

(3) In the first embodiment, each of the data lines 21 (each of the EL bars 20) has the quadrangular prism-like shape. Each positive hole transport layer 23 is thus held in surface-contact with the scanning lines 13, stabilizing electrical connection between the positive hole transport layers 23 and the scanning lines 13. Further, the electric properties of the EL apparatus 10 are stabilized.

Further, since each data line 21 (each EL bar 20) has the quadrangular prism-like shape, a uniform space is defined between the data line 21, or the opposing electrode, and the scanning lines 13, or the transparent electrodes. Accordingly, a functional layer (the light emitting layer 22 and the positive hole transport layer 23) having uniform thickness is formed between each data line 21 and the scanning lines 13. This makes it easy to ensure uniform light emitting intensities in the pixels.

(4) In the first embodiment, the light emitting layer 22 and the positive hole transport layer 23 are formed on the entire outer surface 21a of each data line 21. The light emitting layers 22 and the positive hole transport layers 23 are thus provided between the data lines 21 and the scanning lines 13, regardless of the direction in which the EL bars 20 are oriented. Therefore, even if the EL bars 20 are arranged at inaccurate positions, the light emitting layers 22 and the positive hole transport layers 23 are reliably provided between the data lines 21 and the scanning lines 13. The light L generated in correspondence with each of the data signals is thus radiated from the corresponding one of the light emitting layers 22.

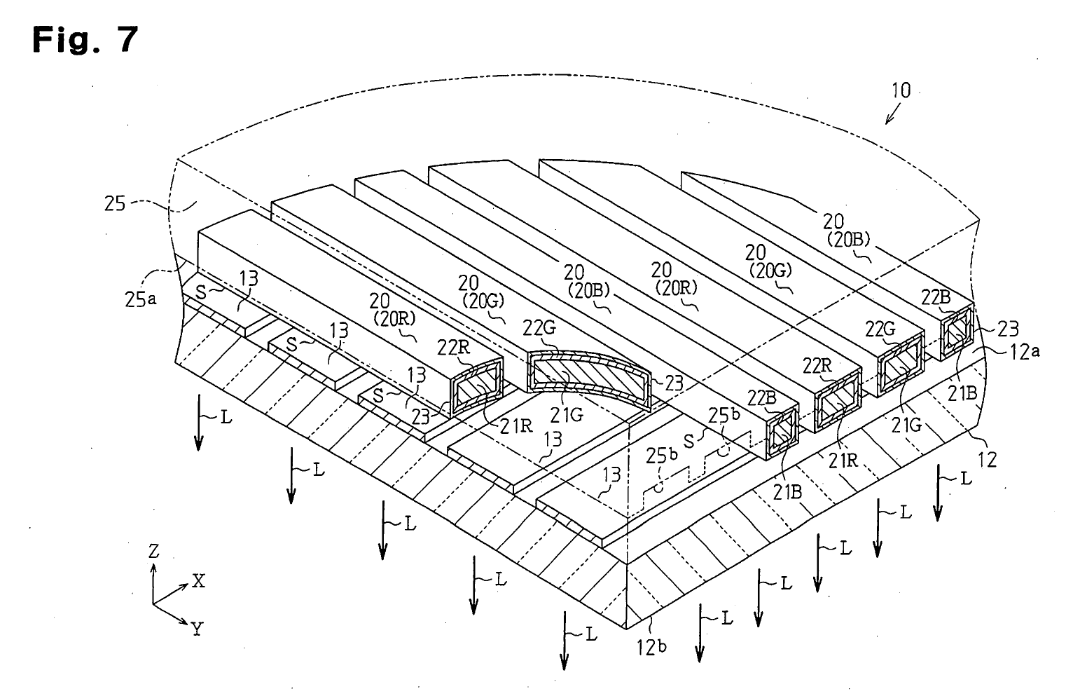

A second embodiment of the present invention will hereafter be described with reference to FIGS. 7 to 10. In the second embodiment, each of the EL bars 20 emits light L of colors different from those of the first embodiment and sized differently from the first embodiment. The following description focuses on the differences between the EL bars 20 of the first embodiment and those of the second embodiment.

As shown in FIG. 7, a plurality of (n) EL bars 20, each of which has a quadrangular prism-like shape and extends in direction Y, are provided on the scanning lines 13 in such a manner as to cross the scanning lines 13. The EL bars 20 are spaced at certain intervals in direction X.

The EL bars 20 include red EL bars 20R, green EL bars 20G, and blue EL bars 20B. The red EL bars 20R, the green EL bars 20G, and the blue EL bars 20B are arranged alternately in this order. A red data line 21R, an opposing electrode, is provided in the core of each of the red EL bars 20R. A green data line 21G, an opposing electrode, is provided in the core of each of the green EL bars 20G. A blue data line 21B, an opposing electrode, is provided in the core of each of the blue EL bars 20B. The lateral width (the dimension in direction X) of each red data line 21R and that of each green data line 21G are greater than that of each blue data line 21B. The red, green, and blue data lines 21R, 21G, 21B are electrically connected to the data line driver circuit 24 (see FIG. 1). The data line driver circuit 24 sends corresponding data signals to the data lines 21R, 21G, 21B at predetermined points of time.

A red light emitting layer 22R is formed on the outer surface of each of the data lines 21R. A green light emitting layer 22G is provided on the outer surface of each of the data lines 21G. A blue light emitting layer 22B is provided on the outer surface of each of the data lines 21B. Each of the light emitting layers 22R, 22G, 22B is an organic layer with uniform thickness formed on the entire outer surface of the corresponding one of the data lines 21R, 21G, 21B. The lateral width of each red light emitting layer 22R and that of each green light emitting layer 22G is greater than the lateral width of each blue light emitting layer 22B in correspondence with the sizes of the data lines 21R, 21G.

Each light emitting layer 22R, 22G, 22B is formed of light emitting layer material that emits light in the wavelength rage corresponding to one of the three primary colors of light. Each red light emitting layer 22R emits light in the wavelength range corresponding to red light. Each green light emitting layer 22G emits light in the wavelength range corresponding to green light. Each blue light emitting layer 22B emits light in the wavelength range corresponding to blue light. In the second embodiment, the red light emitting layers 22R are formed of poly(3-methoxy6-(3-ethylhexyl)paraphenylenevinylene). The green light emitting layers 22G are formed of alternating copolymer of dioctylfluorene and benzothiadiazole. The blue light emitting layers 22B are formed of polydioctylfluorene.

A positive hole transport layer 23 is formed on the outer surface of each of the light emitting layers 22R, 22G, 22B. Each of the positive hole transport layers 23 is an organic layer with uniform thickness formed on the entire outer surface of the corresponding one of the light emitting layers 22R, 22G, 22B. Like the first embodiment, each positive hole transport layer 23 is connected to the scanning lines 13 that cross the positive hole transport layer 23 in a surface contact manner. The lateral width of the positive hole transport layer 23 of each red EL bar 20R and that of the positive hole transport layer 23 of each green EL bar 20G are greater than the lateral width of the positive hole transport layer 23 of each blue EL bar 20B in correspondence with the sizes of the data lines 21R, 21G.

Therefore, the positive hole transport layer 23 of each red data line 21R and the positive hole transport layer 23 of each green data line 21G are each connected to the scanning lines 13 at a surface area greater than the surface area at which the positive hole transport layer 23 of each blue data line 21B are connected to the scanning lines 13.

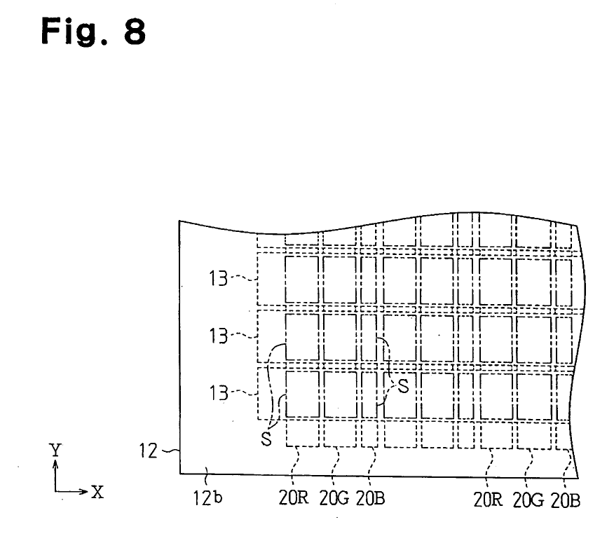

Accordingly, as illustrated in FIG. 8, the sizes of the pixel areas S of the EL bars 20R, 20G, 20B depend on the lateral widths of the EL bars 20R, 20G, 20B. The size of each pixel area S is altered simply by increasing or decreasing the lateral width of the corresponding one of the EL bars 20R, 20G, 20B. In the second embodiment, the lateral width of each red EL bar 20R and that of each green EL bar 20G are greater than the lateral width of each blue EL bar 20B. Thus, the size of each pixel area S corresponding to the red color and the size of each pixel area S corresponding to the green color are greater than the size of each pixel area S corresponding to the blue color.

Referring to FIG. 7, a sealing substrate 25, or a holding portion, is provided over the EL bars 20R, 20G, 20B, like the first embodiment. A plurality of guide grooves 25b, which extend in direction Y, are defined in a holding surface 25a of the sealing substrate 25 and spaced at certain intervals in direction X. The lateral width of each guide groove 25b is substantially equal to the lateral width of the corresponding EL bar 20R, 20G, 20B. The guide grooves 25b are located at positions corresponding to the EL bars 20R, 20G, 20B. Each of the guide grooves 25b guides the corresponding one of the EL bars 20R, 20G, 20B in direction Y.

The positive holes from the scanning lines 13 and the electrons from the data lines 21R, 21G, 21G are injected into the corresponding light emitting layers 22R, 22G, 22B. Through recombining of the positive holes and the electrons, each of the light emitting layers 22R, 22G, 22B associated with the pixel areas S generates excitons (exciters). The excitons release energy when restoring the ground states, thus emitting the light L in the wavelength range corresponding to the specific one of the colors. The light L emitted by each light emitting layer 22R, 22G, 22B passes through the scanning lines 13 and the transparent substrate 12 and exits the transparent substrate 12 through the display surface 12b.

Therefore, in the EL apparatus 10, simply by changing the lateral width of the corresponding EL bars 20R, 20G, 20B, the size of the light exit area (the pixel area S) corresponding to the specific one of the colors is altered. Accordingly, when changing the pixel sizes, the existing EL bars 20 may be used for the pixels the sizes of which are not to be altered. In other words, the lateral width of only the EL bars 20 the pixel size of which is to be changed must be modified. This improves productivity for manufacturing the EL apparatus 10 and reproducibility of the colors of a displayed image.

A method for manufacturing each EL bar 20R, 20G, 20B will hereafter be explained.

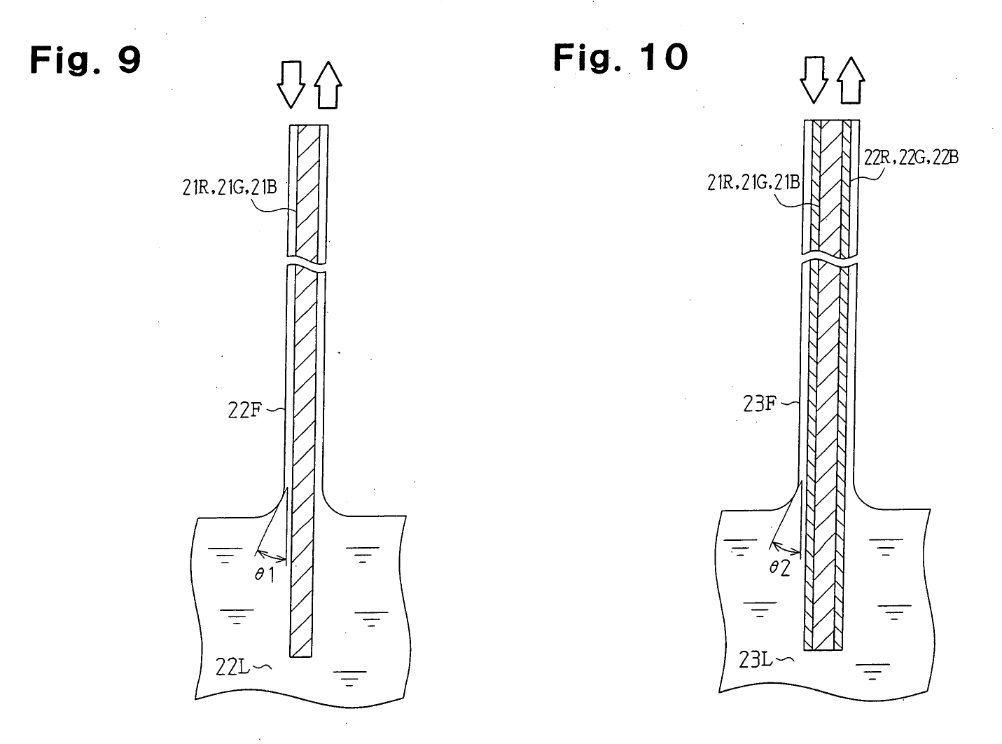

As illustrated in FIG. 9, each of the data lines 21R, 21G, 21B, which is separate from the transparent substrate 12, is immersed into and removed from light emitting layer forming liquid 22L of the corresponding color. A liquid film 22F formed by the light emitting layer forming liquid 22L, which has deposited on the outer surface of the data line 21R, 21G, 21B, is then dried, thus providing the light emitting layer 22R, 22G, 22B of the corresponding color.

That is, the light emitting layers 22R, 22G, 22B are formed for the corresponding data lines 21R, 21G, 21B without involving the transparent substrate 12. The thickness and the quality of each light emitting layer 22R, 22G, 22B depends on the receding contact angle θ1 of the light emitting layer forming liquid 22L with respect to the data line 21R, 21G, 21B and the size of the data line 21R, 21G, 21B. Therefore, to change the sizes of the pixel areas S, adjustment of the conditions for forming the films must be carried out solely for the data lines (for example, the blue data lines 21B) associated with the pixel areas S the sizes of which are to be changed.

After formation of the light emitting layers 22R, 22G, 22B, each of the data lines 21R, 21G, 21B is immersed in and removed from positive hole transport layer forming liquid 23L. A liquid film 23F formed by the positive hole transport layer forming liquid 23L, which has deposited on the light emitting layer 22R, 22G, 22B, is then dried to form the positive hole transport layer 23.

That is, the positive hole transport layers 23 are formed for the corresponding data lines 21R, 21G, 21B without involving the transparent substrate 12. The thickness and the quality of each positive hole transport layer 23 depends on the receding contact angle θ2 of the positive hole transport layer forming liquid 23L with respect to the light emitting layer 22R, 22G, 22B and the size of the data line 21R, 21G, 21B. Therefore, to change the sizes of the pixel areas S, adjustment of the conditions for forming the films must be carried out solely for the data lines (for example, the blue data lines 21B) corresponding to the pixel areas S the sizes of which are to be changed.

The second embodiment, which is configured as above-described, has the following advantages.

(5) In the second embodiment, the EL bars 20R, 20G, 20B with different lateral widths, each of which has the quadrangular prism-like shape, are connected to the scanning lines 13 of the transparent substrate 12. By changing the lateral widths of the EL bars 20R, 20G, 20B, the sizes of the associated pixels areas S are altered for the corresponding EL bars 20R, 20G, 20B.

Therefore, to change the sizes of the pixel areas S, the film forming conditions must be adjusted solely for the data lines associated with the pixels areas S the sizes of which are to be changed. This facilitates changing of the pixel sizes, thus easily improving the color reproducibility of the EL apparatus 10.

(6) In the second embodiment, each of the data lines 21 has the quadrangular prism-like shape and the positive hole transport layers 23 and the scanning lines 13 are mutually held in surface-contact. This stabilizes the electric connection between the positive hole transport layers 23 and the scanning lines 13. The sizes of the pixel areas S are thus accurately regulated. Accordingly, the brightness of the light emitted by each of the pixel areas S is stably controlled to a desired extent.

(7) In the second embodiment, the light emitting layers 22R, 22G, 22B are provided for emitting the lights L corresponding to the three primary colors of light. The pixel areas S corresponding to the red light and the green light are sized greater than the pixel areas S corresponding to the blue light. The sizes of the pixel areas S are thus adapted to the characteristics of human vision. This efficiently reduces the number of the pixels. Further, the color reproducibility using additive color mixing is improved.

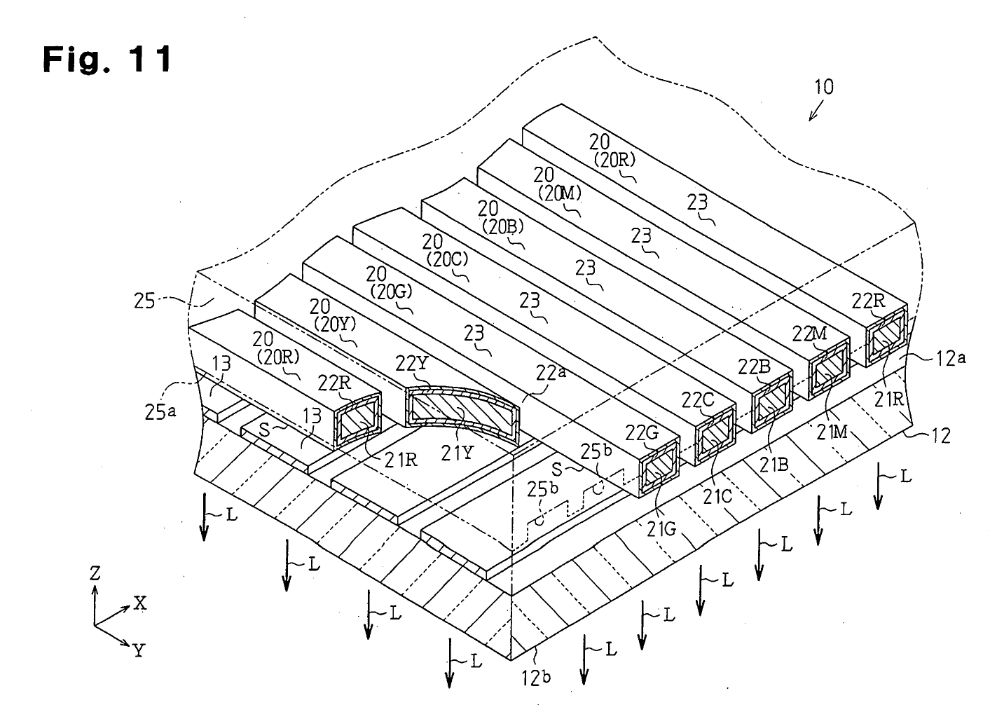

Next, a third embodiment of the present invention will be described with reference to FIG. 11. In the third embodiment, the colors of the lights emitted by the EL bars 20 are modified from those of the first embodiment. Therefore, the following description will focus on the modifications to the EL bars 20.

As shown in FIG. 11, a plurality of (n) EL bars 20, each of which extends in direction Y and has a quadrangular prism-like shape, are provided on the scanning lines 13 in such a manner as to cross the scanning lines 13. The EL bars 20 are spaced at certain intervals in direction X.

The EL bars 20 include red EL bars 20R, yellow EL bars 20Y, and green EL bars 20G and cyan (bluish green) EL bars 20C, blue EL bars 20B, and magenta (reddish purple) EL bars 20M, which correspond to complementary light emitting layers. The EL bars 20 are aligned alternately in the order of red, yellow, green, cyan, blue, and magenta.

A red data line 21R, or an opposing electrode, is provided in the core of each of the red EL bars 20R. A yellow data line 21Y, or an opposing electrode, is provided in the core of each of the yellow EL bars 20Y. A green data line 21G, or an opposing electrode, is provided in the core of each of the green EL bars 20G. A bluish green data line 21C, or an opposing electrode, is provided in the core of each of the bluish green EL bars 20C. A blue data line 21B, or an opposing electrode, is provided in the core of each of the blue EL bars 20B. A reddish purple data line 21M is provided in the core of each of the reddish purple EL bars 20M. The data lines 21R to 21B and 21Y to 21M are electrically connected to the data line driver circuit 24 (see FIG. 1). The data line driver circuit 24 sends corresponding data signals to the data lines 21R to 21B and 21Y to 21M at predetermined points of time.

A red light emitting layer 22R is formed on the outer surface of each of the red data lines 21R. A yellow light emitting layer 22Y is formed on the outer surface of each of the yellow data lines 21Y. A green light emitting layer 22G is formed on the outer surface of each of the green data lines 21G. A bluish green light emitting layer 22C is formed on the outer surface of each of the bluish green data lines 21C. A blue light emitting layer 22B is formed on the outer surface of each of the blue data lines 21B. A reddish purple light emitting layer 22M is formed on the outer surface of each of the reddish purple data lines 21M. Each of the light emitting layers 22R to 22B and 22Y to 22M is an organic layer with uniform thickness formed on the entire outer surface of the corresponding one of the data lines 21R to 21B and 21Y to 21M. Each of the light emitting layers 22R to 22B and 22Y to 22M is formed of organic light emitting layer material that emits light in the wavelength range corresponding to one of the three primary colors of light and the three primary colors of pigment. That is, each red light emitting layer 22R, each yellow light emitting layer 22Y, each green light emitting layer 22G, each bluish green light emitting layer 22C, each blue light emitting layer 22B, and each reddish purple light emitting layer 22M emit light in the wavelength range corresponding to red, yellow, green, bluish green, blue, and reddish purple, respectively.

A positive hole transport layer 23 is formed on the outer surface of each of the light emitting layers 22R to 22B and 22Y to 22M. Each of the positive hole transport layers 23 is an organic layer with uniform thickness formed on the entire outer surface of the corresponding one of the light emitting layers 22R to 22B and 22Y to 22M. Each positive hole transport layer 23 is connected to the scanning lines 13, which cross the positive hole transport layer 23, in a surface contact manner.

As indicated by the double-dotted chain lines, a sealing substrate 25, which forms a portion of a holding portion, is provided over the EL bars 20R to 20B and 20Y to 20M. A plurality of guide grooves 25b, which extend in direction Y, are defined in a holding surface 25a of the sealing substrate 25 and spaced at equal intervals in direction X. The guide grooves 25b are arranged at positions corresponding to the EL bars 20R to 20B and 20Y to 20M. Each of the guide grooves 25b guides the corresponding one of the EL bars 20R to 20B and 20Y to 20M in direction Y.

The positive holes from the scanning lines 13 and the electrons from the data lines 21R to 21B and 21Y to 21M are injected into the corresponding light emitting layers 22R to 22B and 22Y to 22M. The light emitting layers 22R to 22B and 22Y to 22M corresponding to the pixel areas S generate excitons (exciters) through recombining of the positive holes and the electrons. The excitons release energy when restoring the ground states, thus emitting the light L in the wavelength range corresponding to the specific one of the colors. The light L emitted by each light emitting layer 22R to 22B and 22Y to 22M passes through the scanning lines 13 and the transparent substrate 12 and exits the transparent substrate 12 through the display surface 12b.

In this manner, the EL apparatus 10 displays an image based on additive color mixing by means of the read EL bars 20R, the green EL bars 20G, and the blue EL bars 20B, which are aligned on the scanning lines 13. Further, the EL apparatus 10 displays an image based on subtractive color mixing by means of the bluish green EL bars 20C, the reddish purple EL bars 20M, and the yellow EL bars 20Y. As a result, the EL apparatus 10 widens the range of color reproducibility of a displayed image in correspondence with the colors of the EL bars 20, which are aligned on the scanning lines 13. Also, simply by replacing the EL bars 20 that emit light of a desired color with the EL bars 20 that emit light of a different color (for example, white light), the color reproducibility range of the displayed image is further widened.

As in the second embodiment, each light emitting layer 22R to 22B and 22Y to 22M is formed by immersing the corresponding data line 21R to 21B and 21Y to 21M in light emitting layer forming liquid 22L of the corresponding color and drying the obtained liquid film 22F. Also as in the second embodiment, each positive hole transport layer 23 is formed by immersing the corresponding data line 21R to 21B and 21Y to 21M in positive hole transport layer forming liquid 23L and drying the obtained liquid film 23F.

The third embodiment, which is configured as above-described, has the following advantages.

(8) In the third embodiment, each of the light emitting layers 22R to 22B and 22Y to 22M and each of the positive hole transport layers 23 are deposited on the outer surfaces of the corresponding one of the data lines 21R to 21B and 21Y to 21M. In this manner, the EL bars 20R to 20B and 20Y to 20M are provided. The EL bars 20R to 20B and 20Y to 20M are aligned on the scanning lines 13 of the transparent substrate 12 and pressed against the scanning lines 13 by the sealing substrate 25.

Therefore, simply by securing the EL bars 20 corresponding to different colors to the transparent substrate 12, the color reproducible range of the EL apparatus 10 is widened. Specifically, to widen the color reproducible range, simply by checking and adjusting the thickness and the quality of each light emitting layer corresponding to the color (for example, white) the reproducibility of which is to be increased, the color emitting layers are allowed to have uniform thickness and exhibit uniform quality throughout the EL apparatus 10. As a result, more types of light emitting layers can be provided easily, thus facilitating widening of the color reproducible range of the EL apparatus 10.

(9) Further, the additive color mixing through the red EL bars 20R, the green EL bars 20G, and the blue EL bars 20B and the subtractive color mixing through the bluish green EL bars 20C, the reddish purple EL bars 20, and the yellow EL bars 20Y are both employed. This further facilitates widening of the color reproducible range of the EL apparatus 10.

The illustrated embodiments may be modified as follows.

In each of the illustrated embodiments, the functional layer is formed by the light emitting layer and the positive hole transport layer. However, the configuration of the functional layer is not restricted to this. That is, for example, the positive hole transport layer may be omitted. Alternatively, a positive hole injection layer may be formed between the positive hole transport layer and the scanning lines in order to improve injection efficiency of positive holes into the corresponding light emitting layer. Further, an electron barrier layer, which suppresses movement of electrons, may be provided between the positive hole transport layer and the light emitting layer.

As another alternative, an electron transport layer, which transports electrons injected from the data lines to the light emitting layer, may be arranged between the light emitting layer and the data lines. Further, a positive hole barrier layer, which suppresses movement of positive holes, may be arranged between the light emitting layer 22 and the corresponding electron transport layer.

In each of the illustrated embodiments, the light emitting layer may be formed by a white light emitting layer that emits light in the wavelength range corresponding to the white color. Alternatively, the light emitting layer may be formed by the white light emitting layer added to the light emitting layers of different colors. Further, the light emitting layer may be formed by light emitting layers that emit light in two different wavelength ranges corresponding to the red color, light emitting layers that emit light in two different wavelength ranges corresponding to the green color, and light emitting layers that emit light in two different wavelength ranges corresponding to the blue color. In other words, multiple light emitting layers that emit light in different wavelength ranges may be provided for each one of the colors.

In each of the illustrated embodiments, each of the EL bars 20 includes the single light emitting layer. However, instead of this structure, the EL bar 20 may have, for example, a multi-photon structure in which multiple light emitting layers and multiple charge generating layers are alternately provided.

In each of the illustrated embodiments, the light emitting layer and the positive hole transport layer are formed in the entire portion of each data line. However, instead of this configuration, the light emitting layer and the positive hole transport layer may be formed only in a portion of the outer surface of each data line opposed to the transparent substrate 12.

In each of the illustrated embodiments, the outermost circumference of each functional layer is formed by the positive hole transport layer 23. However, instead of this structure, a bonding layer or a conductive layer (for example, a metal film) may be provided on the outer surface of each positive hole transport layer 23. The bonding layer improves bonding performance between the EL bar and the scanning lines 13. The conductive layer reduces electric resistance (contact resistance) between the light emitting layer and the scanning lines 13. This structure further stabilizes the electric properties between the scanning lines 13 and each EL bar 20.

In each of the illustrated embodiments, the holding portion is embodied by the sealing substrate 25 and the sealing layer 26. However, instead of this, the holding portion may be formed by resin that fills the space between each adjacent pair of the EL bars. That is, as long as each EL bar 20 is held by the transparent substrate 12 in such a manner as to connect the EL bar 20 to the transparent substrate 12, the holding portion may be configured in any suitable manner.

In each of the illustrated embodiments, the space between each adjacent pair of the EL bars 20 is filled with inactive gas. However, instead of this, the space between each adjacent pair of the EL bars 20 may be, for example, covered by a light shielding member so that crosstalk between the EL bars 20 can be avoided.

In each of the illustrated embodiments, each EL bar 20 has the quadrangular prism-like shape. However, instead of this shape, the EL bar 20 may have a polygonal prism-like shape having a triangular cross-sectional shape or a pentagonal cross-sectional shape or a cross-sectional shape having more than five sides. Further, the EL bar 20 may be shaped as a pole having an oval cross-sectional shape or a circular cross-sectional shape. In other words, the EL bars 20 may have any other suitable shape, as long as the functional layers are connected to the transparent electrodes.

In each of the illustrated embodiments, the core of each EL bar 20 is formed by the data line. However, instead of this configuration, a separate rod member formed of glass or resin may be employed as the core body of each EL bar 20. In this case, the data line is formed on the outer surface of the core body.

In each of the illustrated embodiments, each scanning line is configured as the transparent electrode and each data line is formed as the opposing electrode. However, instead of this, the scanning line may be formed as the opposing electrode and the data line may be provided as the transparent electrode.

In each of the illustrated embodiments, the light emitting layers and the positive hole transport layers are formed through a liquid-phase process. However, instead of this, these layers may be formed through a gas-phase process such as vapor deposition.

Although the multiple embodiments have been described herein, it will be clear to those skilled in the art that the present invention may be embodied in different specific forms without departing from the spirit of the invention. The invention is not to be limited to the details given herein, but may be modified within the scope and equivalence of the appended claims.

1. An electroluminescence apparatus comprising:
a transparent substrate;
a plurality of transparent electrodes aligned on a surface of the transparent substrate;
a plurality of light emitting bars, each of the light emitting bars including a bar-like opposing electrode and a functional layer, the functional layer including a light emitting layer deposited on an outer surface of the opposing electrode; and
a holding portion that holds the light emitting bars with respect to the surface of the transparent substrate in such a manner that the functional layers are each connected to the transparent electrodes.

2. The apparatus according to claim 1,
wherein the light emitting bars have light emitting layers that emit light of different colors.

3. The apparatus according to claim 1,
wherein the opposing electrodes have different thicknesses,
wherein each of the light emitting layers emits light of a color predetermined in correspondence with the thickness of the corresponding one of the opposing electrodes.

4. The apparatus according to claim 2,
wherein the light emitting bars include:
red light emitting bars having red light emitting layers that emit red light;
green light emitting bars having green light emitting layers that emit green light; and
blue light emitting bars having blue light emitting layers that emit blue light.

5. The apparatus according to claim 4,
wherein the thickness of each of the red light emitting bars is greater than the thickness of each of the blue light emitting bars,
wherein the thickness of each of the green light emitting bars is greater than the thickness of each of the blue light emitting bars.

6. The apparatus according to claim 3,
wherein the light emitting bars include at least one complementary color light emitting bar having a complementary color light emitting layer that emits light of a complementary color of any one of red, green, and blue.

7. The apparatus according to claim 1,
wherein each of the functional layers is held in surface-contact with the corresponding one of the transparent electrodes.

8. The apparatus according to claim 1,
wherein each of the opposing electrodes has a rectangular cross-sectional shape as viewed in the axial direction.

9. The apparatus according to claim 1, wherein the holding portion includes:
a holding substrate arranged at a position opposed to the transparent substrate, the holding substrate maintaining electric connection between the functional layer and the transparent electrodes by pressing the light emitting bars against the transparent substrate; and
a sealing layer arranged between the transparent substrate and the holding substrate for sealing a space between the transparent substrate and the holding substrate.

10. The apparatus according to claim 1,
wherein the functional layers include at least one of a positive hole transport layer, a positive hole barrier layer, an electron transport layer, and an electron barrier layer.

11. A method for manufacturing an electroluminescence apparatus, the method comprising:
aligning a plurality of transparent electrodes on a surface of a transparent substrate;
forming a plurality of light emitting bars by providing a functional layer including a light emitting layer on an outer surface of each of bar-like opposing electrodes; and
securing the light emitting bars to the surface of the transparent substrate in such a manner that the functional layers are each connected to the transparent electrodes.

12. The method according to claim 11,
wherein the light emitting bars are formed by depositing light emitting layers that emit light of different colors on the corresponding opposing electrodes.

13. The method according to claim 11,
wherein the opposing electrodes have different thicknesses,
wherein the method further includes forming the light emitting bars by providing a light emitting layer that emits light of a color predetermined in correspondence with the thickness of the corresponding opposing electrode in the opposing electrode.
